(19) United States
(12) Patent Application Publication
(10) Pub. No.: US 2024/0035154 A1
(43) Pub. Date: Feb. 1, 2024

(54) FLUORINE BASED CLEANING FOR PLASMA DOPING APPLICATIONS

(71) Applicant: Applied Materials, Inc., Santa Clara, CA (US)

(72) Inventors: Vikram M. Bhosle, North Reading, MA (US); Meng Cai, North Andover, MA (US); Deven Matthew Raj Mittal, Middleton, MA (US); Vincent Deno, Wenham, MA (US)

(21) Appl. No.: 17/874,951

(22) Filed: Jul. 27, 2022

(51) Int. Cl. C23C 16/44; H01J 37/32

(52) U.S. Cl. CPC C23C 16/4405; H01J 37/32862

(57) ABSTRACT

A method of cleaning a plasma chamber is disclosed. Periodically, a cleaning process is performed. The cleaning process comprises introducing a mixture of fluoride molecules and argon into the plasma chamber and creating a plasma. The fluoride molecules are ionized and interact with the deposited material on the chamber walls. This causes the fluorine ions to bond to the deposited material, which typically results in a gas that can be exhausted from the plasma chamber. When the deposited material has been removed, the amount of free fluorine within the plasma chamber increases. This increase in fluorine may be used to determine when the plasma chamber is cleaned.

### FIELD

Embodiments of the present disclosure relate to a system and method for cleaning a plasma doping chamber using a fluorine-based cleaning gas.

### BACKGROUND

Plasma chambers are used to implant dopant species into a workpiece that is disposed in the chamber. In operation, a dopant species, typically in the form of a gas, is introduced into the plasma chamber, and a plasma is created, typically through the use of RF energy. The ions are then attracted to the workpiece through the use of bias voltage.

Over time, some of the dopant material may become deposited on the interior surfaces of the walls and window of the plasma chamber. For example, if the dopant species is arsenic, the walls may be coated by an arsenic-based compound. This deposited material may reduce the efficiency of the plasma chamber. Further, the deposited material may flake off and become embedded in the workpiece, thus impacting yield.

To address this issue, it is common to perform a cleaning process periodically to remove this deposited material. In certain embodiments, this cleaning process comprises introducing a cleaning species, typically nitrogen trifluoride gas, into the plasma chamber. A cleaning plasma is then created using this cleaning species. The ions of the cleaning species from the cleaning plasma interact with the deposited material, removing this deposited material from the walls and window.

However, it has been discovered that this cleaning process may stall. A stalled cleaning process is characterized by the fact that the thickness of the deposited material on the walls is no longer decreasing in the presence of the cleaning plasma. Without being bound to any particular theory, it is believed that the nitrogen in the cleaning species forms a nitride layer on top of the deposited material, causing the cleaning process to stall.

Therefore, in some systems, a passivation cycle is intermittently performed during the cleaning process. A passivation cycle introduces a passivation species, which may be hydrogen based gas, such as an argon-hydrogen mixture, into the plasma chamber. This passivation species may be effective in allowing the cleaning process to continue after being stalled.

After the passivation cycle is completed, the cleaning process may continue until it stalls again. This sequence of cleaning process and passivating cycle may repeat a number of times until the deposited material is removed. The number of iterations is based on the thickness of the deposited material and the level of desired cleanliness, and may be difficult to quantify.

Therefore, it would be beneficial if these was a system and method for cleaning plasma chambers that did not have these limitations. Further, it would be advantageous if there was a clear determination that the plasma chamber was clean so that the operator was aware when workpiece processing could resume.

### SUMMARY

A method of cleaning a plasma chamber is disclosed. Periodically, a cleaning process is performed. The cleaning process comprises introducing a mixture of fluoride molecules and argon into the plasma chamber and creating a plasma. The fluoride molecules are ionized and interact with the deposited material on the chamber walls. This causes the fluorine ions to bond to the deposited material, which typically results in a gas that can be exhausted from the plasma chamber. When the deposited material has been removed, the amount of free fluorine within the plasma chamber increases. This increase in fluorine may be used to determine when the plasma chamber is cleaned.

According to one embodiment, a method of operating a plasma doping (PLAD) system is disclosed. The method comprises processing a plurality of workpieces inside a plasma chamber by creating a plasma using a dopant species, wherein some of the dopant species is deposited on interior surfaces of the plasma chamber during the processing; and cleaning the interior surfaces of the plasma chamber, after processing the plurality of workpieces, by creating a cleaning plasma using a cleaning species, wherein the cleaning species comprises a mixture of fluorine molecules and one or more insert species. In some embodiments, no nitrogen-based molecules are used in the cleaning. In some embodiments, the dopant species is AsH₃, PH₃ or B₂H₆. In some embodiments, the one or more inert species is argon, and wherein an amount of argon in the mixture is 80% or more. In some embodiments, the cleaning is terminated after a predetermined length of time, wherein the predetermined length of time is determined based on the dopant species and the number of workpieces that were processed. In some embodiments, an optical emission spectroscopy system is used to monitor an amount of fluorine in the plasma chamber during the cleaning, and the cleaning is terminated based on a criterion related to the amount of fluorine in the plasma chamber. In certain embodiments, the cleaning is terminated when the amount of fluorine in the plasma chamber reaches a predetermined threshold. In certain embodiments, the cleaning is terminated when the amount of fluorine in the plasma chamber reaches a predetermined threshold and remains above that predetermined threshold for a predetermined duration of time. In certain embodiments, the cleaning is terminated when the amount of fluorine in the plasma chamber increases at a rate greater than a predetermined threshold. In certain embodiments, the cleaning is terminated when a ratio of the amount of fluorine in the plasma chamber to the amount of a second species exceeds a predetermined threshold. In certain embodiments, the second species comprises the dopant species. In certain embodiments, the second species comprises at least one of the one or more inert species. In some embodiments, an optical emission spectroscopy system is used to monitor an amount of the dopant species in the plasma chamber during the cleaning, and wherein the cleaning is terminated based on a criterion related to the amount of dopant species in the plasma chamber.

According to another embodiment, a cleaning system for use with a plasma doping (PLAD) system is disclosed. The cleaning system comprises a cleaning gas source, wherein the cleaning gas comprises a mixture of fluorine molecules and one or more inert gasses; an optical emission spectroscopy (OES) system; and a controller, wherein the controller: enables the flow of the cleaning gas into a plasma chamber of the PLAD system to initiate a cleaning process; monitors an amount of fluorine in the plasma chamber during the cleaning process using the OES system; and terminates the cleaning process based on a criterion related to the amount of fluorine in the plasma chamber. In some embodiments, the controller terminates the cleaning process when the amount of fluorine in the plasma chamber reaches a predetermined threshold. In some embodiments, the controller terminates the cleaning process when the amount of fluorine in the plasma chamber reaches a predetermined threshold and remains above that predetermined threshold for a predetermined duration of time. In some embodiments, the controller terminates the cleaning process when the amount of fluorine in the plasma chamber increases at a rate greater than a predetermined threshold. In some embodiments, the controller terminates the cleaning process when a ratio of the amount of fluorine in the plasma chamber to the amount of a second species exceeds a predetermined threshold. In certain embodiments, the second species comprises the dopant species. In certain embodiments, the second species comprises at least one of the one or more inert gasses.

### BRIEF DESCRIPTION OF THE FIGURES

For a better understanding of the present disclosure, reference is made to the accompanying drawings, which are incorporated herein by reference and in which:

FIG. 1 is a plasma chamber in accordance with one embodiment;

FIG. 2 is a flowchart showing the operation of the plasma chamber according to one embodiment; and

FIG. 3 shows two graphs showing the removal of material from the interior walls as a function of time.

### DETAILED DESCRIPTION

As described above, the present disclosure describes a system and method for cleaning a plasma chamber.

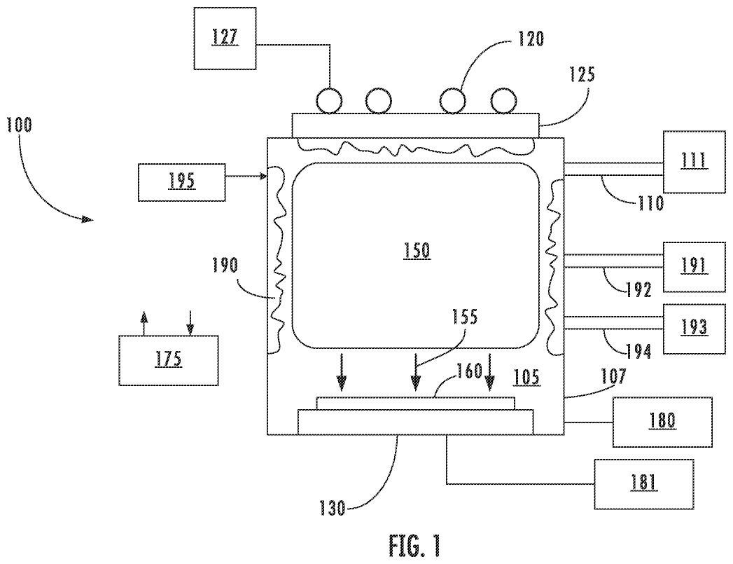

FIG. 1 shows a PLAD (plasma doping) system 100. The PLAD system 100 includes a plasma chamber 105 defined by several walls 107, which may be constructed from graphite, silicon, silicon carbide, aluminum, or another suitable material. This plasma chamber 105 may be supplied with a feed gas, which is contained in a feed gas source 111, via a feed gas inlet 110. This feed gas may be energized by a plasma generator. In some embodiments, an RF antenna 120 or another mechanism is used to create plasma 150. The RF antenna 120 is in electrical communication with a RF power supply 127 which supplies power to the RF antenna 120. A dielectric window 125, such as a quartz or alumina window, may be disposed between the RF antenna 120 and the interior of the plasma chamber 105.

Ions 155 in the plasma 150, which are positively charged, are attracted to the workpiece 160 by the difference in potential between the plasma chamber 105 (which defines the potential of the plasma 150) and the workpiece 160. In some embodiments, the walls 107 may be more positively biased than the workpiece 160. For example, the walls 107 may be in electrical communication with a chamber power supply 180, which is positively biased. In this embodiment, the workpiece 160 is in communication with a platen 130, which is in communication with bias power supply 181, which is biased at a voltage lower than that applied by chamber power supply 180. In certain embodiments, the bias power supply 181 may be maintained at ground potential. In a second embodiment, the chamber power supply 180 may be grounded, while the bias power supply 181 may be biased at a negative voltage. While these two embodiments describe either the workpiece 160 or the walls 107 being at ground potential, other embodiments are also possible. The ions 155 from the plasma 150 are attracted to the workpiece 160 as long as the walls 107 are biased at a voltage greater than the voltage applied to the platen 130.

The feed gas source 111 may be any suitable gas. For example, the feed gas source 111 may contain a gas that contains arsenic, boron or phosphorus. The gas may be, for example, AsH₃, PH₃ or B₂H₆.

In addition, a cleaning species may be contained within the cleaning gas source 191. The cleaning gas source 191 is in communication with the plasma chamber 105 via a cleaning gas inlet 192. The cleaning species may be a mixture of fluorine molecules (F₂) and argon. The mixture may be 20% fluorine molecules, with the rest being argon. In other embodiments, the percentage of fluorine molecules may be lower. In this disclosure, percentages are given as molar percentages.

In other embodiments, the cleaning species contained within the cleaning gas source 191 may be 20% fluorine molecules and 80% argon. In addition, there may be an additional diluent gas source 193 filled with argon, which is also in communication with the plasma chamber 105 via diluent gas inlet 194. In this embodiment, the percentage of fluorine molecules used during the cleaning process is reduced by the inclusion of additional argon from the diluent gas source 193. In other embodiments, the diluent gas source 193 is not present.

In certain embodiments, the various gas sources may be containers, such as canisters that hold the respective gas.

Further, while the above passage describes the use of argon with fluorine molecules, other inert gases may be utilized. For example, other inert gasses such as helium, neon or xenon may be used as the cleaning species. Additionally, the cleaning species (the gas in cleaning gas source 191) may contain argon while the diluent gas disposed in the diluent gas source 193 contains a different inert gas. In other embodiments, a different inert gas is used for both the cleaning species and the diluent gas.

In certain embodiments, the cleaning species comprises no nitrogen-based molecules. In certain embodiments, the cleaning species consists of fluorine molecules and one or more inert gasses, where the inert gasses may be helium, argon, neon or xenon. Further, in some embodiments, when utilized, the diluent gas consists of an inert gas.

The PLAD system 100 also includes a controller 175. The controller 175 may be a general purpose computer, a specially processing unit or another suitable computing device. Further, the controller 175 includes a memory device having instructions that enable the controller 175 to perform the functions described herein.

The controller 175 may receive input signals from a variety of systems and components and provide output signals to each to control the same. For example, the controller 175 may control the flow of feed gas, cleaning gas and diluent gas. Further, the controller 175 may control the voltages applied by the RF power supply 127, chamber power supply 180 and bias power supply 181. Further, the controller 175 may be in communication with an OES system 195, as described in more detail below.

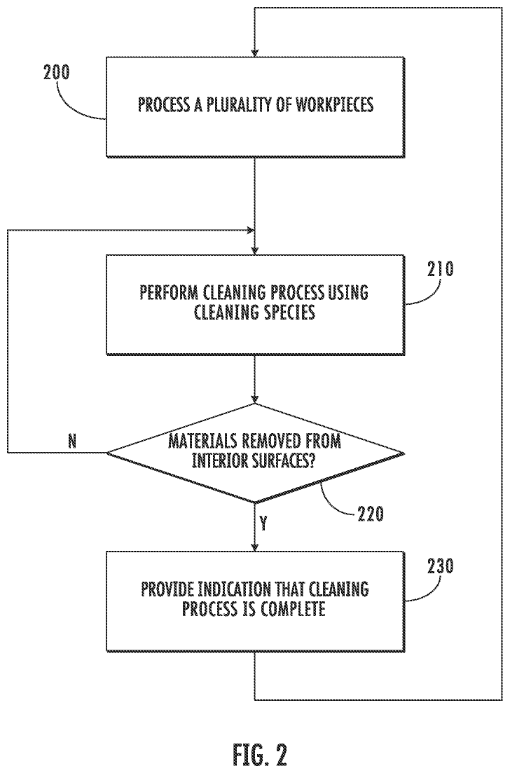

Having described the structure of the PLAD system 100, its operation will now be described. FIG. 2 shows a flowchart of the operation of the PLAD system 100.

First, as shown in Box 200, the PLAD system 100 is used to process a plurality of workpieces. The processing of the workpieces comprising introducing the feed gas into the plasma chamber 105. Additionally, the RF power supply 127 is actuated to supply RF energy to the antenna 120. This creates a plasma 150. The ions from within the plasma 150 are attracted to the workpiece 160 due to the difference in voltage between the workpiece 160 and the plasma 150. Thus, the controller 175 may vary the voltage applied by at least one of chamber power supply 180 and bias power supply 181 to attract ions to the workpiece 160. After the desired dose of ions has been implanted into the workpiece 160, the workpiece 160 is removed and a subsequent workpiece is placed in the plasma chamber 105.

As workpieces are processed, material 190 may be deposited on the walls 107. This material 190 is a byproduct of the feed gas, and as such, the material 190 may comprise a compound that includes arsenic, phosphorus or boron, depending on the feed gas that is being used. After a plurality of workpieces have been processed, the thickness of the material 190 that is deposited may grow to an unacceptable level.

At this point, it may be beneficial to perform a cleaning process, as shown in Box 210. This may be performed by introducing a cleaning species into the plasma chamber 105. During the cleaning process, the cleaning species and optionally the diluent gas are introduced into the plasma chamber 105 via the cleaning gas inlet 192 and diluent gas inlet 194. The feed gas is no longer flowing into the plasma chamber 105 during this cleaning process. The total flow rate of the cleaning species and diluent gas may be 600 sccm or more. The workpieces are removed from the plasma chamber 105 during the cleaning process. However, the chamber power supply 180 and bias power supply 181 may be maintained at the same voltage so that ions are not attracted to the platen 130. Energy is provided to the antenna 120 by the RF power supply 127 so as to create a plasma 150. The argon in the cleaning species is used to stabilize the plasma 150. The fluorine ions in the plasma 150 react with the material 190 on the interior surfaces of the walls 107 and the dielectric window 125, reducing the thickness of the material 190.

The controller 175 may monitor the cleaning process to determine when the material 190 has been completely or nearly completely removed from the interior surfaces, as shown in Box 220. These interior surfaces include the interior surfaces of the walls 107 and the dielectric window 125.

For example, in certain embodiments, the cleaning process is terminated based on a predetermined duration of time. For example, through empirical testing, it may be determined that a sufficient amount of the material 190 is removed from the interior surfaces of the plasma chamber 105 after a cleaning process having a predetermined length of time, where that predetermined length of time is based on the dopant species and the number of workpieces that have been processed since the last cleaning process.

In other embodiments, an optical emission spectroscopy (OES) system 195 may be used in conjunction with the plasma chamber 105 and the controller 175. An OES system 195 is used to detect the presence of different elements in a sample. As the cleaning species is introduced to the plasma chamber 105, the fluorine ions react with the material 190 on the walls 107. As the material 190 is consumed, there is more free fluorine. Consequently, the amount of fluorine detected by the OES system 195 increases as the material 190 is removed from the interior surfaces.

Thus, in one embodiment, the controller 175 may terminate the cleaning process when the fluorine concentration, as detected by the OES system 195, exceeds a predetermined limit. Fluorine concentration is typically detected by the OES system 195 by monitoring the output at 703 nm. The predetermined limit, and the predetermined thresholds described below, may be determined empirically, as is well known to those skilled in the art.

In another embodiment, the controller 175 may terminate the cleaning process when the fluorine concentration, as detected by the OES system 195, increases at a rate greater than a predetermined threshold. Specifically, as the fluorine is first introduced, it reacts with the material 190 on the walls 107. As the material 190 is consumed, there is more free fluorine. When all of the material 190 is consumed, all of the fluorine in the plasma become free fluorine. This may result in a rapid increase in the amount of fluorine detected by the OES system 195.

In another embodiment, the controller 175 may terminate the cleaning process when the fluorine concentration, as detected by the OES system 195, remains above a predetermined threshold for a predetermined amount of time. In other words, in the embodiment, the controller 175 waits until the fluorine concentration exceeds a predetermined threshold and remains above this threshold for a predetermined amount of time. Again, the predetermined threshold and predetermined amount of time may be determined empirically by those skilled in the art.

In yet another embodiment, the controller 175 may terminate the cleaning process based on a ratio of fluorine concentration to the concentration of a second species.

In one embodiment, the second species is the dopant species (such as boron, arsenic or phosphorus). In this embodiment, it is assumed that the material 190 on the walls 107 is the dopant species from the feed gas. Thus, when the cleaning gas is initially introduced, the concentration of dopant species may be high, while the concentration of fluorine may be lower. As the material 190 reacts with the fluorine ions, the concentration of the dopant species may decrease, while the concentration of fluorine increases.

In yet another embodiment, the controller 175 may terminate the cleaning process based on a ratio of fluorine concentration to inert gas concentration. When the cleaning gas is introduced, the fluorine reacts with material on the walls 107. However, the inert gas does not react. Thus, the concentration of inert gas is not affected by the cleaning process and is only dependent on the flow rate. In contrast, the fluorine concentration is dependent on both the cleaning process and the flow rate. Thus, the use of this ratio may help normalize the results with respect to flow rate.

In yet another embodiment, the controller 175 may monitor the concentration of the dopant species in the plasma chamber 105. When the concentration of the dopant species decreases below a predetermined threshold, the controller 175 may determine that the material 190 has been removed, and the cleaning process may be terminated.

Thus, the controller 175 may use the information from the OES system 195 to terminate the cleaning process based on one or more of a plurality of different criteria.

In other words, in some of these embodiments, the controller 175 determines whether the cleaning process is completed using a criterion based on the amount of fluorine detected in the plasma chamber. In certain embodiments, the criterion also includes the amount of other gases detected in the plasma chamber. In other embodiments, the controller 175 determines whether the cleaning process is completed using a criterion based on the amount of dopant species detected in the plasma chamber.

If the controller 175 determines that the cleaning process has completed, it may provide an indication to the operator or other system so that the cleaning process is complete and that processing of workpieces may recommence, as shown in Box 230. If, however, the controller 175 determines that the cleaning process is not complete, the cleaning process continues, as shown in Box 210.

Thus, in certain embodiments, the present disclosure describes cleaning system for use with a plasma doping (PLAD) system. The cleaning system comprises a cleaning gas source 191 and optionally a diluent gas source 193 in communication with the plasma chamber 105, an OES system 195 and a controller 175.

The controller 175 may control the introduction of the cleaning species into the plasma chamber 105. As noted above, the cleaning species comprises a mixture of fluorine molecules and one or more inert gasses, such as helium, argon, neon or xenon. In some embodiments, 80% or more of the mixture is the one or more inert gasses, with the remainder being fluorine molecules. No nitrogen-based molecules are included in the cleaning species.

Further, during the cleaning process, the controller 175 may use the OES system 195 to monitor at least the amount of fluorine in the plasma chamber 105 during the cleaning process. When a criterion, which is related to the amount of fluorine in the plasma chamber 105, is reached, the controller 175 may provide an indication that the cleaning process is complete. The criterion used by the controller 175 may be any of those described above.

The embodiments described above in the present application may have many advantages.

First, this new cleaning method is suitable for many dopant species, including AsH₃, PH₃ and B₂H₆. It is especially useful if a nitride layer is created during the cleaning process when NF 3 is used.

Additionally, many workpieces that are processed are coated with photoresist material. During the processing, the photoresist material may also be deposited on the walls 107, along with the dopant species. The photoresist material typically contains carbon and oxygen may be used to help remove the carbon from the walls. The new cleaning method described herein is compatible with the use of oxygen. This allows this cleaning method to be utilized with workpieces that are at least partly coated with a photoresist material. Thus, in this embodiment, the cleaning species may be combined with oxygen and/or a diluent gas. In certain embodiments, during the cleaning process, only the cleaning species, oxygen and a diluent gas are introduced. In certain other embodiments, only the cleaning species and oxygen are introduced.

Second, when compared to NF₃, this cleaning process may be beneficial for reducing the greenhouse footprint, since NF₃ is considered a highly potent greenhouse gas.

Third, this cleaning species enables a much faster and more effective cleaning of the plasma chamber 105. For example, in one test, the plasma chamber was cleaned after 2,5000 workpieces were processed. The plasma chamber was cleaned using a conventional cleaning species (NF₃). The test was repeated using a cleaning species that comprised a mixture of fluorine molecules and argon. The cleaning process that used the mixture having fluorine molecules took at least 25% less time. This improvement increases if the cleaning process using NF₃ stalls, as a passivation cycle is then used. In fact, in one test where 7,500 workpieces were processed before cleaning, the cleaning time was reduced by more than 40% as compared to the conventional cleaning species by using the mixture comprising fluorine molecules and argon. This may lead to considerable cost of ownership savings due to increases operational time and reduced preventative maintenance time.

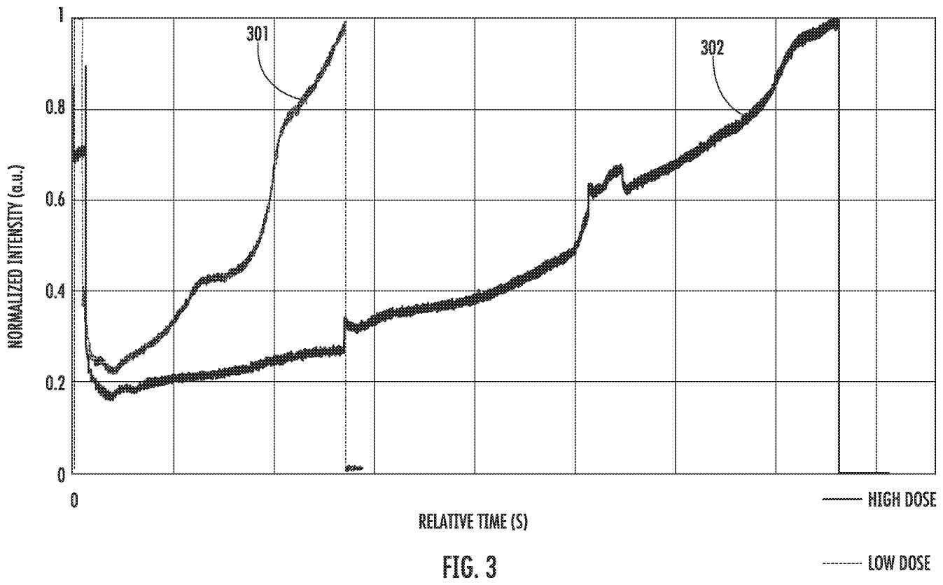

Fourth, the use of fluorine molecules removes the material 190 in a very predictable manner. In fact, the vertical axis of FIG. 3 shows the output of an OES system 195, and specifically, the concentration of fluorine, which emits energy at 703 nm. The horizontal axis represents time. Line 301 shows the concentration of fluorine in the plasma chamber 105 after roughly 2,500 workpieces are processed. Note that the fluorine concentration reaches the peak at a first time duration. Line 302 shows the concentration of fluorine in the plasma chamber 105 after roughly 7,500 workpieces are processed. Note that the fluorine concentration reaches the peak after a second time duration, which is roughly 3 times greater than the first time duration. The thickness of the material 190 on the interior surfaces increases roughly linearly with the number of the workpieces that are processed. In other words, line 302 represents a scenario where the thickness of the material 190 deposited on the interior surfaces is roughly three times thicker than the scenario shown by line 301. Note that the cleaning time also increased by roughly a factor of three as well. This helps demonstrate that a cleaning species using fluorine molecules operates continuously, without stalling, to reduce the material 190.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method of operating a plasma doping (PLAD) system, consisting sequentially of:
processing a plurality of workpieces inside a plasma chamber of the PLAD system by creating a plasma using arsine (AsH₃), wherein some arsenic from the arsine is deposited on interior surfaces of the plasma chamber during the processing;
cleaning the arsenic from the interior surfaces of the plasma chamber, wherein the plurality of workpieces are removed from the plasma chamber before the cleaning, by creating a cleaning plasma using a cleaning species, wherein the cleaning species consists of a mixture of fluorine molecules and one or more inert species; and
optionally monitoring an amount of the fluorine molecules, at least one of the one or more inert species and/or arsenic during the cleaning using an optical emission spectroscopy (OES) system.

2. (canceled)

3. (canceled)

4. The method of claim 1, wherein the one or more inert species is argon, and wherein an amount of argon in the mixture is 80% or more, wherein percentages are molar percentages.

5. The method of claim 1, wherein the cleaning is terminated after a predetermined length of time, wherein the predetermined length of time is determined based on a number of workpieces that were processed.

6. (canceled)

7. The method of claim 1, further consisting of monitoring the amount of fluorine molecules in the plasma chamber during the cleaning, wherein the cleaning is terminated when the amount of fluorine in the plasma chamber reaches a predetermined threshold.

8. The method of claim 1, further consisting of monitoring the amount of fluorine molecules in the plasma chamber during the cleaning, wherein the cleaning is terminated when the amount of fluorine molecules in the plasma chamber reaches a predetermined threshold and remains above that predetermined threshold for a predetermined duration of time.

9. The method of claim 1, further consisting of monitoring the amount of fluorine molecules in the plasma chamber during the cleaning, wherein the cleaning is terminated when the amount of fluorine molecules in the plasma chamber increases at a rate greater than a predetermined threshold.

10. The method of claim 1, further consisting of monitoring the amount of fluorine molecules and arsenic in the plasma chamber during the cleaning, wherein the cleaning is terminated when a ratio of the amount of fluorine molecules in the plasma chamber to an amount of arsenic exceeds a predetermined threshold.

11. (canceled)

12. The method of claim 1, further consisting of monitoring the amount of fluorine molecules and at least one of the one or more inert species, wherein the cleaning is terminated when a ratio of the amount of fluorine molecules in the plasma chamber to an amount of the at least one of the one or more inert species exceeds a predetermined threshold.

13. The method of claim 1, further consisting of monitoring an amount of the arsenic in the plasma chamber during the cleaning, and wherein the cleaning is terminated when the amount of the arsenic in the plasma chamber decreases below a predetermined threshold.

14. (canceled)

15. (canceled)

16. (canceled)

17. (canceled)

18. (canceled)

19. (canceled)

20. (canceled)
